(19) United States
(12) Patent Application Publication
(10) Pub. No.: US 2026/0282747 A1
(43) Pub. Date: Sep. 17, 2026

(54) MODULAR GEOTHERMAL POWER GENERATION SYSTEM

(71) Applicant: Shenzhen University, Shenzhen (CN)

(72) Inventors: Xiting LONG, Shenzhen (CN); Heping XIE, Shenzhen (CN); Licheng SUN, Shenzhen (CN); Tianyi GAO, Shenzhen (CN); Entong XIA, Shenzhen (CN); Shuheng LI, Shenzhen (CN); Jun WANG, Shenzhen (CN)

(21) Appl. No.: 19/334,787

(22) Filed: Sep. 19, 2025

Related U.S. Application Data
(63) Continuation of application No. PCT/CN2024/100166, filed on Jun. 19, 2024.

(30) Foreign Application Priority Data
Jul. 3, 2023 (CN) 202310810112.2

(51) Int. Cl. H10N 19/00; F24T 50/00

(52) U.S. Cl. CPC H10N 19/101; F24T 50/00

(57) ABSTRACT

A modular geothermal power generation system comprises a plurality of groups of thermoelectric power generation modules, a hot water supply system and a cold water supply system. The thermoelectric power generation module comprises at least two heat exchangers arranged adjacent to each other at an interval, the adjacent two heat exchangers are respectively a hot heat exchanger and a cold heat exchanger, a plurality of thermoelectric modules for thermoelectric power generation are arranged between the two heat exchangers, the hot water supply system is connected with the hot heat exchanger, and the cold water supply system is connected with the cold heat exchanger. A hot end and a cold end are formed by oppositely arranging the hot heat exchanger and the cold heat exchanger, and the thermoelectric module is arranged between the hot end and the cold end, so that a whole structure is modularized.

### CROSS-REFERENCE TO RELATED APPLICATIONS

This application is a continuation of International Patent Application No. PCT/CN2024/100166 with a filing date of Jun. 19, 2024, designating the United States, now pending, and further claims priority to Chinese Patent Application No. 202310810112.2 with a filing date of Jul. 3, 2023. The content of the aforementioned applications, including any intervening amendments thereto, are incorporated herein by reference.

### TECHNICAL FIELD

The present invention relates to the technical field of geothermal power generation, in particular to a modular geothermal power generation system.

### BACKGROUND OF THE PRESENT INVENTION

Most of existing geothermal power generation systems convert thermal energy into mechanical energy, and then into electrical energy. In the process, there are inevitable disadvantages such as mechanical loss, and pipeline scaling, and the whole system is relatively complex which needs to be optimized urgently.

A thermoelectric material is a functional material which can realize direct conversion from thermal power to electricity. Internal carriers thereof move directionally under an action of temperature difference, and a stable electric potential difference is formed at both ends of the material. Specifically, when different temperatures are applied to two ends of the thermoelectric material, a Seebeck effect will lead to a change of charge distribution inside the thermoelectric material, resulting in a stable electric potential difference, thus generating a current. A thermoelectric power generation technology based on the thermoelectric material breaks through a traditional energy conversion path of thermal energy-mechanical energy-electric energy, avoids an intermediate process of mechanical work, and realizes the direct conversion from thermal power to electricity, which has the unique advantages of simple operation, no mechanical energy loss, stability, reliability, and green cleaning, etc.

At present, a research and development team has designed a geothermal thermoelectric generator, which verifies the feasibility of applying the thermoelectric power generation technology to medium and low temperature geothermal power generation. However, an installed capacity of the equipment is limited. Secondly, due to the adoption of integral design, the equipment is bulky and does not have good expansibility, and it is not convenient for future operation and maintenance, so it is difficult to achieve large-scale engineering application.

### SUMMARY OF THE PRESENT INVENTION

The present invention aims to provide a modular geothermal power generation system in allusion to the shortcomings of the prior art, and the modular geothermal power generation system has good expandability and is convenient for assembly and maintenance.

A modular geothermal power generation system comprises a plurality of groups of thermoelectric power generation modules;

a hot water supply system; and

a cold water supply system;

wherein the thermoelectric power generation module comprises at least two heat exchangers, which are arranged adjacent to each other at an interval, the adjacent two heat exchangers are respectively a hot heat exchanger and a cold heat exchanger, a plurality of thermoelectric modules for thermoelectric power generation are arranged between the two heat exchangers, the hot water supply system is connected with the hot heat exchanger, and the cold water supply system is connected with the cold heat exchanger.

Further, at least two thermoelectric power generation modules form one power generation group, the heat exchanger comprises a heat dissipation housing, two ends of the heat dissipation housing are respectively provided with a water inlet interface and a water outlet interface, the hot water supply system and the cold water supply system are respectively arranged at left and right sides of the thermoelectric power generation module, the hot water supply system comprises a hot water input pipe and a hot water output pipe, and the cold water supply system comprises a cold water input pipe and a cold water output pipe.

The hot heat exchanger and the cold heat exchanger are correspondingly connected between the two adjacent thermoelectric power generation modules in the power generation group through a pipeline, so that the hot heat exchanger and the cold heat exchanger of each thermoelectric power generation module are correspondingly connected in series; the thermoelectric power generation modules located on two sides of the power generation group are a main thermoelectric power generation module and a secondary thermoelectric power generation module, the water inlet interface of the hot heat exchanger of the main thermoelectric power generation module is connected with the hot water input pipe through a pipeline, and the water outlet interface of the hot heat exchanger of the secondary thermoelectric power generation module is connected with the hot water output pipe through a pipeline; the water inlet interface of the cold heat exchanger of the main thermoelectric power generation module is connected with the cold water input pipe through a pipeline, and the water outlet interface of the cold heat exchanger of the secondary thermoelectric power generation module is connected with the cold water output pipe through a pipeline.

Further, the thermoelectric power generation module comprises 2K+1 heat exchangers, and K is a natural number, wherein K heat exchangers are the hot heat exchangers; K+1 heat exchangers are the cold heat exchangers, and the hot heat exchanger is arranged between two adjacent cold heat exchangers; the thermoelectric power generation module further comprises a fixing structure for fixing the heat exchanger, and the fixing structure comprises two clamping plates, which are fixedly connected through a connecting piece.

Further, the heat dissipation housing comprises a cover plate and a bottom shell, the bottom shell comprises a bottom plate, a middle part of the bottom plate is provided with a plurality of ribs arranged at intervals, the ribs are arranged along a length direction of the heat exchanger to divide an internal space of the heat exchanger into a plurality of channels, and the water inlet interface and the water outlet interface are respectively arranged at a lower end of a left side and an upper end of a right side of the heat dissipation housing.

Preferably, both a left side plate and a right side plate of the bottom shell are arranged obliquely; a distance between a left end face of the rib and the left side plate increases gradually from top to bottom, and a distance between a right end face of the rib and the right side plate decreases gradually from top to bottom.

Further, the modular geothermal power generation system further comprises a bracket for fixing the thermoelectric power generation module; the bracket comprises a bottom plate, a supporting plate is arranged in a middle part of the bottom plate, two side faces of the supporting plate are respectively connected with a plurality of bearing plates arranged at intervals, and the thermoelectric power generation module is fixed on the bearing plates.

Further, the two thermoelectric power generation modules form one power generation group, the hot water input pipe and the hot water output pipe are located at a front end and a back end of one side of the thermoelectric power generation module, the cold water input pipe and the cold water output pipe are located at a front end and a back end of the other side of the thermoelectric power generation module, a side face of the hot water input pipe is connected with a plurality of hot water input manifolds which are transversely arranged, the hot water input manifold is connected with the water inlet interface of the hot heat exchanger through a pipeline, the hot water output pipe is connected with a plurality of hot water output manifolds which are transversely arranged, the hot water output manifold is connected with the water outlet interface of the hot heat exchanger through a pipeline, the hot water input manifolds and the hot water output manifolds are alternately arranged; a side face of the cold water input pipe is connected with a plurality of cold water input manifolds which are transversely arranged, the cold water input manifold is connected with the water inlet interface of the cold heat radiator through a pipeline, the cold water output pipe is connected with a plurality of cold water output manifolds which are transversely arranged, the cold water output manifold is connected with the water outlet interface of the cold heat exchanger through a pipeline; and the cold water input manifolds and the cold water output manifolds are alternately arranged.

Further, a box body is further comprised, the thermoelectric power generation module, the cold water supply system, the hot water supply system and the bracket are all arranged in the box body, and an outer side of the box body is provided with an interface connected with the cold water supply system and an interface connected with the hot water supply system.

Further, a control system is arranged at an upper end of the box body, and the control system is used for monitoring a working state of the cold water supply system, a working state of the hot water supply system and a working state of the thermoelectric power generation module.

The present invention has the beneficial effects that: according to the present invention, a hot end and a cold end are formed by oppositely arranging the hot heat exchanger and the cold heat exchanger are, and the thermoelectric module is arranged between the hot end and the cold end, so that a whole structure is modularized, a use quantity may be adjusted according to requirements, and the modular geothermal power generation system is convenient for maintenance and assembly.

### DESCRIPTION OF THE DRAWINGS

FIG. 1 is a schematic structural diagram of the embodiment.

FIG. 2 is a schematic diagram of removing a box body and a control system from FIG. 1.

FIG. 3 is a schematic diagram of FIG. 2 from another view.

FIG. 4 is a schematic diagram of a thermoelectric power generation module.

FIG. 5 is an exploded schematic diagram of FIG. 4.

FIG. 6 is a partially exploded schematic diagram of removing the thermoelectric power generation module from FIG. 3.

FIG. 7 is a schematic structural diagram of a heat exchanger.

FIG. 8 is a schematic sectional diagram of FIG. 7.

FIG. 9 is a schematic diagram of cooperation among a power generation group, a thermoelectric power generation module and a hot water supply system.

FIG. 10 is an exploded schematic diagram of FIG. 1.

FIG. 11 is a schematic diagram of the power generation group.

### REFERENCE NUMERALS IN THE DRAWINGS

1 - control system; 2 - box body; 3 - thermoelectric power generation module; 4 - cold water supply system; 5 - hot water supply system; and 6 - bracket;

12 - DC electronic load; 13 - programmable logic controller; 14 - touch display screen;

31 - heat exchanger; 32 - thermoelectric module; 33 - heat dissipation housing; 34 - silicone sheet; 36 - clamping plate; 37 - connecting piece; 311 - water inlet interface; 312 - water outlet interface; 331 - rib; 332 - right side plate; 333 - channel; 38 - main thermoelectric power generation module; and 39 - secondary thermoelectric power generation module;

41 - cold water outlet pipe; 42 - cold water input manifold; 43 - cold water output manifold; and 44 - cold water inlet pipe; and

51 - hot water input manifold; 52 - hot water output manifold; 53 - hot water outlet pipe; and 54 - hot water inlet pipe.

### DETAILED DESCRIPTION OF PREFERRED EMBODIMENTS

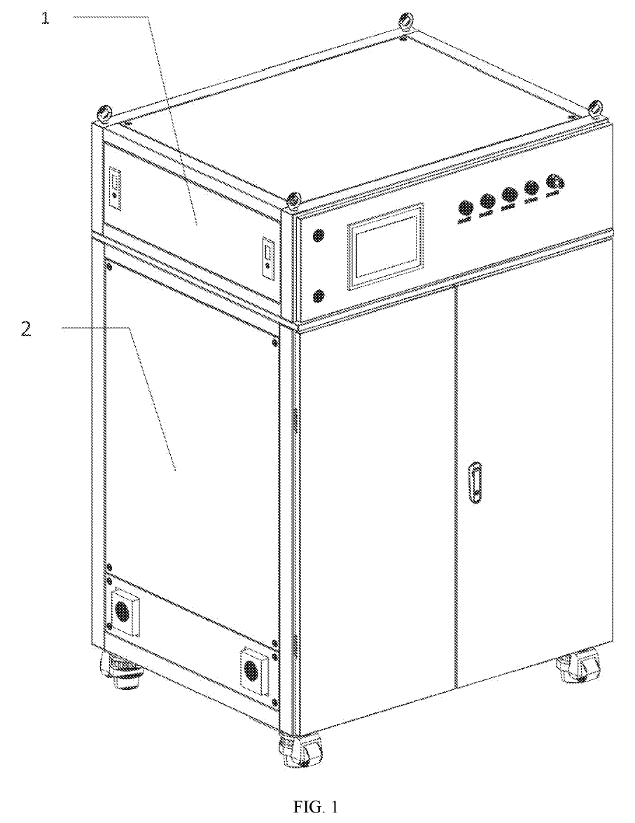

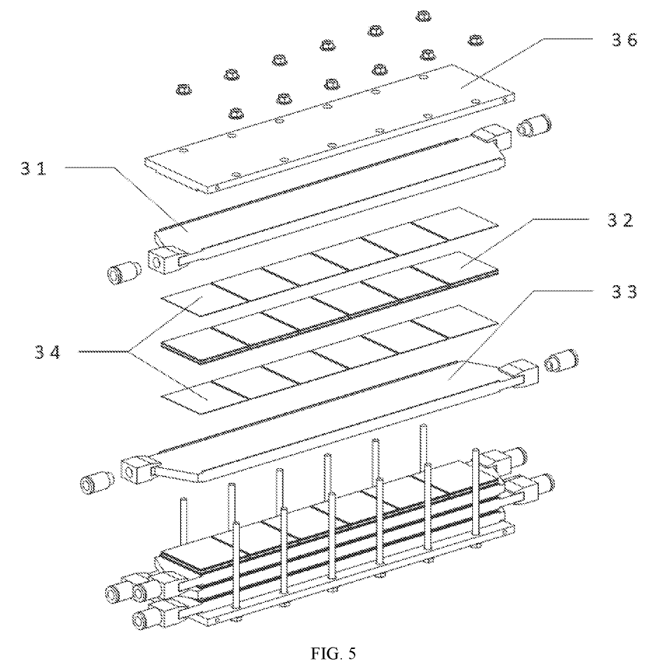

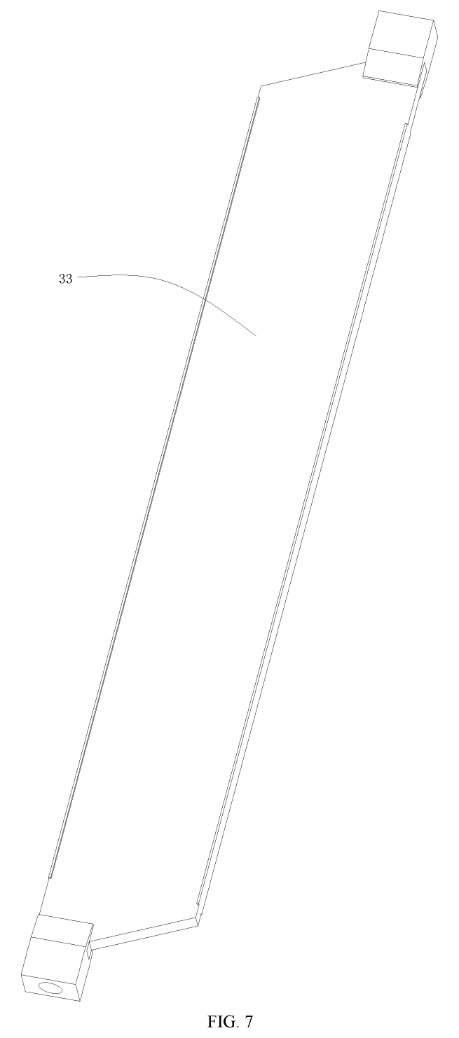

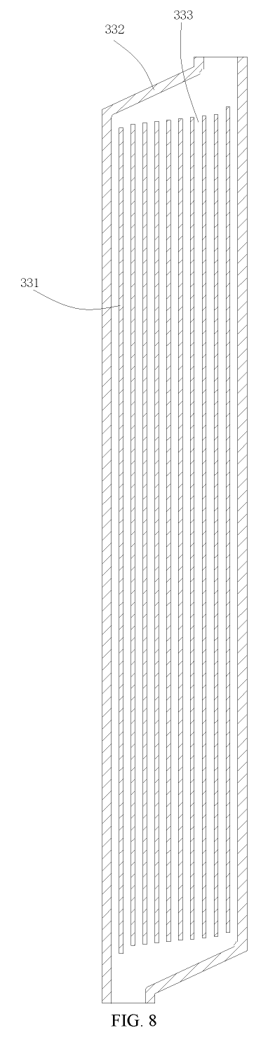

The present invention will be described in detail with reference to the accompanying drawings, as shown in FIGS. 1-11.

Embodiments: referring to FIGS. 1-5, a modular geothermal power generation system comprises a plurality of groups of thermoelectric power generation modules 3;

a hot water supply system 5; and

a cold water supply system 4.

The thermoelectric power generation module 3 comprises at least two heat exchangers 31.The heat exchangers 31 are arranged adjacent to each other at an interval, and the adjacent two heat exchangers 31 are respectively a hot heat exchanger 31 and a cold heat exchanger 31. A plurality of thermoelectric modules 32 for thermoelectric power generation are arranged between the two heat exchangers 31, the hot water supply system 5 is connected with the hot heat exchanger 31, and the cold water supply system 4 is connected with the cold heat exchanger 31.

When the technical solution is implemented, the thermoelectric power generation module 3 is modularized, so that a corresponding quantity of thermoelectric power generation modules 3 can be set in the technical solution according to requirements. During concrete implementation, the thermoelectric module 32 of each group of thermoelectric power generation module is connected with a power generation circuit through a wire, and generated electric energy is output to the outside through the power generation circuit. The power generation circuit belongs to the prior art, and is not a technological innovation of the present invention, so the power generation circuit is not repeated here. During the implementation, the hot water supply system 5 provides hot water to the hot heat exchanger 31, and the cold water supply system 4 provides cold water to the cold heat exchanger 31. A hot end and a cold end are formed on two sides of the thermoelectric module 32, and an electric potential difference is generated between the hot end and the cold end to form electric energy and output the electric energy to the outside. By modular design of the thermoelectric module 32, the thermoelectric module has good expansibility in application and is convenient for assembly and maintenance. Preferably, two sides of the thermoelectric module are both provided with flexible silicone sheet, and are abutted with the heat exchanger through the radiating fins 34.

Further, at least two thermoelectric power generation modules 3 form one power generation group. The heat exchanger 31 comprises one heat dissipation housing 33, and two ends of the heat dissipation housing 33 are respectively provided with a water inlet interface 311 and a water outlet interface 312. The hot water supply system 5 and the cold water supply system 4 are respectively arranged at left and right sides of the thermoelectric power generation module 3. The hot water supply system 5 comprises a hot water input pipe 54 and a hot water output pipe 5. The cold water supply system 4 comprises a cold water input pipe 44 and a cold water output pipe 41.

The hot heat exchanger 31 and the cold heat exchanger 31 are correspondingly connected between the two adjacent thermoelectric power generation modules 3 in the power generation group through a pipeline, so that the hot heat exchanger 31 and the cold heat exchanger 31 of each thermoelectric power generation module 3 are correspondingly connected in series. Referring to FIG. 11, the thermoelectric power generation modules 3 located on two sides of the power generation group are a main thermoelectric power generation module 38 and a secondary thermoelectric power generation module 39. The two sides herein refer to two outermost sides. When the power generation group is distributed vertically, the two groups of thermoelectric power generation modules 3 located at a lowermost side and an uppermost side are the main thermoelectric power generation module 38 and the secondary thermoelectric power generation module 39. When the power generation group is arranged horizontally, the two groups of thermoelectric power generation modules 3 located at the outermost sides are the main thermoelectric power generation module 38 and the secondary thermoelectric power generation module 39.

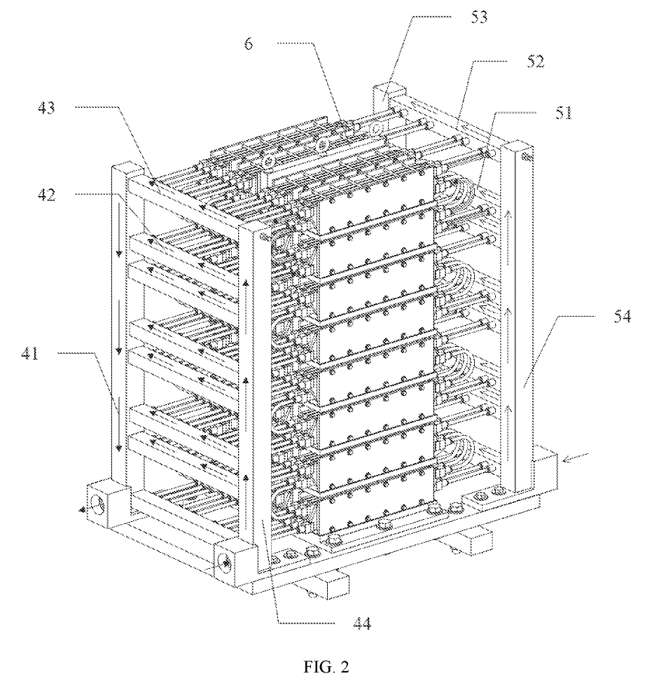

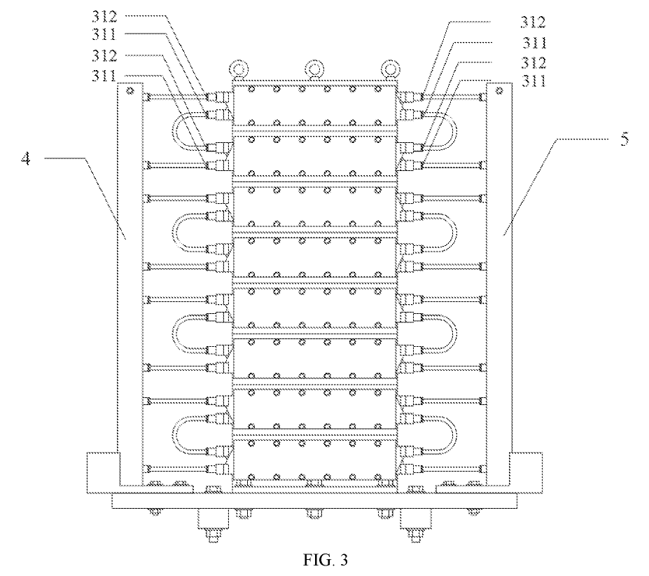

The water inlet interface 311 of the hot heat exchanger of the main thermoelectric power generation module 38 is connected with the hot water input pipe 54 through a pipeline, and the water outlet interface 312 of the hot heat exchanger of the secondary thermoelectric power generation module 39 is connected with the hot water output pipe 53 through a pipeline. The water inlet interface 311 of the cold heat exchanger of the main thermoelectric power generation module 38 is connected with the cold water input pipe 44 through a pipeline, and the water outlet interface 312 of the cold heat exchanger of the secondary thermoelectric power generation module 39 is connected with the cold water output pipe 41 through a pipeline, as shown in FIG. 2, FIG. 3 and FIG. 11.

In practical application, one thermoelectric power generation module 3 is directly connected with the cold water supply system 4 and the hot water supply system 5. An amount of heat exchange is relatively small due to a relatively fast water flow, resulting in small temperature changes of hot water and cold water, and low thermoelectric conversion efficiency. If the flow rate of water flow is reduced, a temperature difference between the cold heat exchanger 31 and the hot heat exchanger 31 will become small, reducing a thermoelectric conversion power. If the heat exchanger 31 is prolonged, a volume of the whole device will become large. In order to balance the above problems well, the applicant develops a series connection mode, in which at least two thermoelectric power generation modules 3 are connected in series through a pipeline, and the pipeline may be a flexible corrugated pipe. In this embodiment, two thermoelectric power generation modules 3 are connected in series, and are arranged up and down. For the convenience of understanding, the upper thermoelectric power generation module 3 is the secondary thermoelectric power generation module 39, and the lower thermoelectric power generation module 3 is the main thermoelectric power generation module 38.

The water inlet interface 311 on a right side of the hot heat exchanger 31 of the main thermoelectric power generation module 38 is connected with the hot water inlet pipe 54 through a straight pipeline, and the water outlet interface 312 on a left side of the hot heat exchanger 31 of the main thermoelectric power generation module 38 is connected with the water inlet interface 311 on a left side of the hot heat exchanger 31 of the secondary thermoelectric power generation module 39 through a U-shaped pipeline. The water outlet interface 312 on a right side of the hot heat exchanger of the secondary thermoelectric power generation module 39 is connected with the hot water outlet pipe through a straight pipeline to form a hot water circulation.

The water inlet interface 311 on a left side of the cold heat exchanger 31 of the main thermoelectric power generation module 38 is connected with the cold water inlet pipe 44 through a straight pipeline, and the water outlet interface 312 on a right side of the cold heat exchanger 31 of the main thermoelectric power generation module 38 is connected with the water inlet interface 311 on a right side of the cold heat exchanger 31 of the secondary thermoelectric power generation module 39 through a U-shaped pipeline. The water outlet interface 312 on a left side of the cold heat exchanger 31 of the secondary thermoelectric power generation module 39 is connected with the cold water outlet pipe 41 through a straight pipeline to form a cold water circulation.

In order to facilitate pipeline connection, when adjacent thermoelectric power generation modules 3 are connected in series, the water outlet interface of the hot heat exchanger 31 of one thermoelectric power generation module 3 and the water inlet interface of the hot heat exchanger 31 of another thermoelectric power generation module 3 are located at the same side and connected through a pipeline, wherein the water outlet interface of the cold heat exchanger 31 of one thermoelectric power generation module 3 and the water outlet interface of the cold heat exchanger 31 of another thermoelectric power generation module 3 are located at the same side and connected through a pipeline.

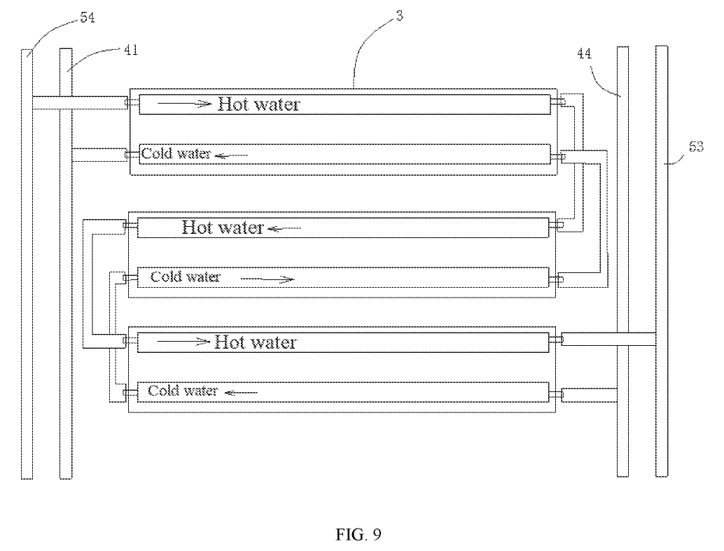

Referring to FIG. 9; when 2N+1 (for example, 3) thermoelectric power generation modules 3 are connected in series, the cold water inlet pipe 44 and the cold water outlet pipe 41 are located at two sides of the thermoelectric power generation module 3, while the hot water outlet pipe 53 and the hot water inlet pipe 54 are also located at the two sides of the thermoelectric power generation module 3. In this case, both the hot water and the cold water flow in S lines.

Secondly, in the same thermoelectric power generation module 3, the cold water and the hot water flow in two opposite routes, with the hot water from left to right and the cold water from right to left, or vice versa, so that a relative temperature differences between the cold heat exchanger 31 and the hot heat exchanger 31 on the two sides of the thermoelectric power generation module 3 do not fluctuate greatly, and working states of the thermoelectric modules 32 in the thermoelectric power generation module 3 are basically consistent, which is beneficial to collection of the electric energy.

Further, the thermoelectric power generation module 3 comprises 2K+1 heat exchangers 31, and K is a natural number, wherein K heat exchangers 31 are the hot heat exchangers 31; K+1 heat exchangers 31 are the cold heat exchangers 31, and the hot heat exchanger 31 is arranged between two adjacent cold heat exchangers 31. The thermoelectric power generation module further comprises a fixing structure for fixing the heat exchanger 31, the fixing structure comprises c, and the two clamping plates 36 are fixedly connected through a connecting piece 37.

During the concrete implementation, the thermoelectric power generation module is arranged between the cold heat exchanger 31 and the hot heat exchanger 31. If the outermost heat exchanger 31 is provided with the hot heat exchanger 31, the hot heat exchanger 31 will exchange heat with the outside, and some heat will be lost. In order to maximize utilization of heat, the cold heat exchangers 31 are arranged at the outermost sides on the two sides, and the hot heat exchanger 31 is arranged in the middle. K may be 1, 2, 3, 4, 5, or the like.

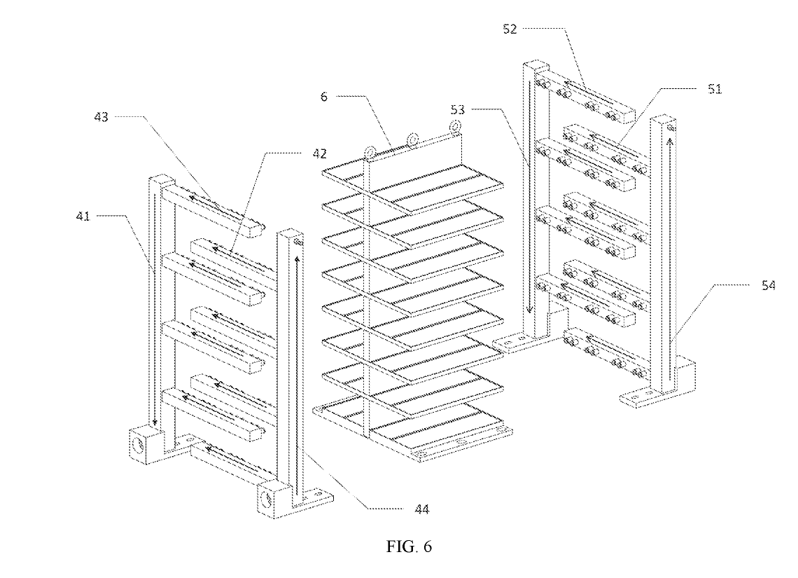

Referring to FIG. 6 and FIG. 7, the heat dissipation housing 33 comprises a cover plate and a bottom shell. The bottom shell comprises a bottom plate, and a middle part of the bottom plate is provided with a plurality of ribs 331 arranged at intervals. The ribs 331 are arranged along a length direction of the heat exchanger 31 to divide an internal space of the heat exchanger 31 into a plurality of channels 333, and the water inlet interface 311 and the water outlet interface 312 are respectively arranged at a lower end of a left side and an upper end of a right side of the heat dissipation housing 33.

Preferably, both a left side plate and a right side plate 332 of the bottom shell are arranged obliquely; a distance between a left end face of the rib and the left side plate increases gradually from top to bottom, and a distance between a right end face of the rib and the right side plate 332 decreases gradually from top to bottom.

In order to reduce a turbulent flow inside the heat exchanger 31, the ribs 331 are arranged in the heat dissipation housing 33 to form a plurality of channels 333. Because a width of the heat exchanger 31 is larger than a width of the interface, the cold water or the hot water enters from the interface. If the heat exchanger 31 is made into a regular rectangle, different velocity layers will be formed inside the heat exchanger 31, which will lead to a temperature difference on a surface of the heat exchanger 31 and affect a working efficiency of the thermoelectric power generation module. The inventor has designed a similar heat exchanger 31 before, in which a flow rate of the channel 333 may be adjusted and balanced by designing ends of the ribs 331 with different radians. But this brings difficulty to production. In order to facilitate production and balance the flow rate of each channel 333, the left side plate and the right side plate 332 of the bottom plate are set in an inclined shape with an inclination angle of 15-30 degrees in the technical solution. After the left side plate and the right side plate are arranged in the inclined shape, water pressures at the left end and the right end of the heat exchanger 31 are adjusted, so that pressure differences at the left end and the right end of all the channels 333 are equal or approximately equal, so that the water flow velocities of the channels 333 are approximately equal; therefore, the heat exchangers 31 keep consistent temperature in a width direction, maintain a linear temperature difference in a length direction, and an equal or approximately equal temperature difference between the cold heat exchanger 31 and the hot heat exchanger 31 is maintained in the length direction, so that the thermoelectric power generation module works stably.

Secondly, the ribs 331 may further reinforce a structure of the heat exchanger. The temperature of the heat exchanger in the length direction is gradually increased or reduced. The heat exchanger is generally made of metal and thermal expansion and contraction dimensions of the heat exchanger are different, which easily leads to formation of a large internal stress, thus resulting in deformation of the cover plate and the bottom shell and affecting thermal contact with the thermoelectric module. After the rib 331 is added, an overall strength is improved, and the deformation may be reduced or avoided.

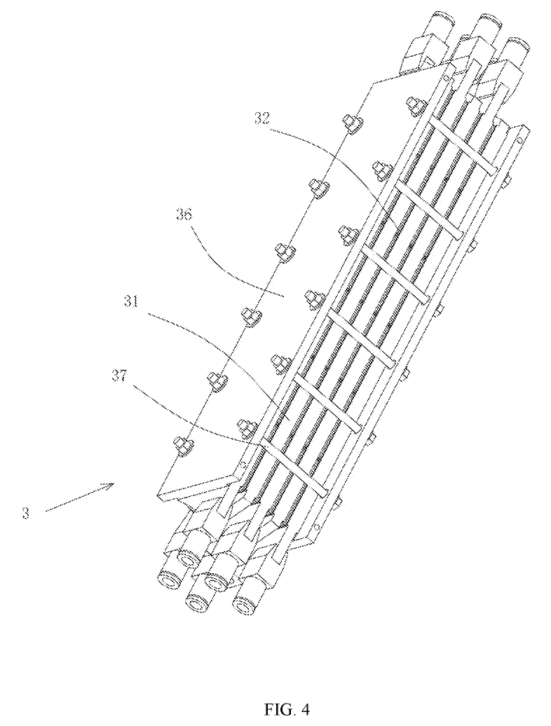

Referring to FIG. 4, further, the modular geothermal power generation system further comprises a bracket 6 for fixing the thermoelectric power generation module 3. The bracket 6 comprises a bottom plate, a supporting plate is arranged in a middle part of the bottom plate, two side faces of the supporting plate are respectively connected with a plurality of bearing plates arranged at intervals, and the thermoelectric power generation module 3 is fixed on the bearing plates.

The thermoelectric power generation module 3 may be conveniently fixed by arranging the bracket 6.

Further, the two thermoelectric power generation modules 3 form one power generation group, the hot water input pipe 54 and the hot water output pipe are located at a front end and a back end of one side of the thermoelectric power generation module 3, while the cold water input pipe 44 and the cold water output pipe 41 are located at a front end and a back end of the other side of the thermoelectric power generation module 3. A side face of the hot water input pipe 54 is connected with a plurality of hot water input manifolds 51 which are transversely arranged, and the hot water input manifold 51 is connected with the water inlet interface 311 of the hot heat exchanger 31 through a pipeline. The hot water output pipe is connected with a plurality of hot water output manifolds 52 which are transversely arranged, and the hot water output manifold 52 is connected with the water outlet interface 312 of the hot heat exchanger 31 through a pipeline. The hot water input manifolds 51 and the hot water output manifolds 52 are alternately arranged. A side face of the cold water input pipe 44 is connected with a plurality of cold water input manifolds 42 which are transversely arranged, and the cold water input manifold 42 is connected with the water inlet interface 311 of the cold heat exchanger through a pipeline. The cold water output pipe 41 is connected with a plurality of cold water output manifolds 43 which are transversely arranged, and the cold water output manifold 43 is connected with the water outlet interface 312 of the cold heat exchanger through a pipeline. The cold water input manifolds 42 and the cold water output manifolds 43 are alternately arranged.

The two thermoelectric power generation modules 3 form one power generation group, so that the cold water input pipe 44 and the cold water output pipe 41 are located at the same side, while the hot water input pipe 54 and the hot water output pipe 53 are located at the same side, which is convenient to manage; secondly, the cold water input manifolds 42 and the cold water output manifolds 43 are alternately arranged; and the hot water input manifolds 51 and the hot water output manifolds 52 are alternately arranged, so that a space is reasonably utilized.

Referring to FIG. 1, further, a box body 2 is further comprised, wherein the thermoelectric power generation module 3, the cold water supply system 4, the hot water supply system 5 and the bracket 6 are all arranged in the box body 2, and an outer side of the box body 2 is provided with an interface connected with the cold water supply system 4 and an interface the hot water supply system 5.

In order to protect normal operation of the thermoelectric power generation module 3 and prevent the cold water supply system 4 and the hot water supply system 5 from external interference, the box body 2 is provided according to the technical solution, and meanwhile, the interfaces are further provided to connect with the cold water supply system 4 and the hot water supply system 5, so as to facilitate inflow and outflow of the hot water and the cold water. Geothermal water may be used for as the hot water and river water may be used as the cold water.

Referring to FIG. 1 and FIG. 10, further, a control system 1 is arranged at an upper end of the box body 2, and the control system 1 is used for monitoring a working state of the cold water supply system 4, a working state of the hot water supply system 5 and a working state of the thermoelectric power generation module 3.

Preferably, a monitoring system comprises a DC electronic load 12, a programmable logic controller 13 and a touch display screen 14.

The above contents are only preferred embodiments of the present invention. According to the idea of the present invention, there will be some changes in the concrete implementation and application scope for those of ordinary skills in the art, and the contents of the specification should not be construed as limitations to the present invention.

We claim:

1. A modular geothermal power generation system, comprising
a plurality of groups of thermoelectric power generation modules,
a hot water supply system; and
a cold water supply system;
wherein the thermoelectric power generation module comprises at least two heat exchangers, which are arranged adjacent to each other at an interval, the adjacent two heat exchangers are respectively a hot heat exchanger and a cold heat exchanger, a plurality of thermoelectric modules for thermoelectric power generation are arranged between the two heat exchangers, the hot water supply system is connected with the hot heat exchanger, and the cold water supply system is connected with the cold heat exchanger;
wherein at least two thermoelectric power generation modules form one power generation group, the heat exchanger comprises a heat dissipation housing, two ends of the heat dissipation housing are respectively provided with a water inlet interface and a water outlet interface, the hot water supply system and the cold water supply system are respectively arranged at left and right sides of the thermoelectric power generation module, the hot water supply system comprises a hot water input pipe and a hot water output pipe, and the cold water supply system comprises a cold water input pipe and a cold water output pipe;
the hot heat exchanger and the cold heat exchanger are correspondingly connected between the two adjacent thermoelectric power generation modules in the power generation group through a pipeline, so that the hot heat exchanger and the cold heat exchanger of each thermoelectric power generation module are correspondingly connected in series; the thermoelectric power generation modules located on two sides of the power generation group are a main thermoelectric power generation module and a secondary thermoelectric power generation module, the water inlet interface of the hot heat exchanger of the main thermoelectric power generation module is connected with the hot water input pipe through a pipeline, and the water outlet interface of the hot heat exchanger of the secondary thermoelectric power generation module is connected with the hot water output pipe through a pipeline; the water inlet interface of the cold heat exchanger of the main thermoelectric power generation module is connected with the cold water input pipe through a pipeline, and the water outlet interface of the cold heat exchanger of the secondary thermoelectric power generation module is connected with the cold water output pipe through a pipeline;
the heat dissipation housing comprises a cover plate and a bottom shell, the bottom shell comprises a bottom plate, a middle part of the bottom plate is provided with a plurality of ribs arranged at intervals, the ribs are arranged along a length direction of the heat exchanger to divide an internal space of the heat exchanger into a plurality of channels, and the water inlet interface and the water outlet interface are respectively arranged at a lower end of a left side and an upper end of a right side of the heat dissipation housing;
the thermoelectric power generation module comprises 2K+1 heat exchangers, and K is a natural number, wherein K heat exchangers are the hot heat exchangers; K+1 heat exchangers are the cold heat exchangers, and the hot heat exchanger is arranged between two adjacent cold heat exchangers; the thermoelectric power generation module further comprises a fixing structure for fixing the heat exchanger, and the fixing structure comprises two clamping plates, which are fixedly connected through a connecting piece;
both a left side plate and a right side plate of the bottom shell are arranged obliquely; a distance between a left end face of the rib and the left side plate increases gradually from top to bottom, and a distance between a right end face of the rib and the right side plate decreases gradually from top to bottom;
the two thermoelectric power generation modules form one power generation group, the hot water input pipe and the hot water output pipe are located at a front end and a back end of one side of the thermoelectric power generation module, the cold water input pipe and the cold water output pipe are located at a front end and a back end of the other side of the thermoelectric power generation module, a side face of the hot water input pipe is connected with a plurality of hot water input manifolds which are transversely arranged, the hot water input manifold is connected with the water inlet interface of the hot heat exchanger through a pipeline, the hot water output pipe is connected with a plurality of hot water output manifolds which are transversely arranged, the hot water output manifold is connected with the water outlet interface of the hot heat exchanger through a pipeline, the hot water input manifolds and the hot water output manifolds are alternately arranged; a side face of the cold water input pipe is connected with a plurality of cold water input manifolds which are transversely arranged, the cold water input manifold is connected with the water inlet interface of the cold heat radiator through a pipeline, the cold water output pipe is connected with a plurality of cold water output manifolds which are transversely arranged, the cold water output manifold is connected with the water outlet interface of the cold heat exchanger through a pipeline; and the cold water input manifolds and the cold water output manifolds are alternately arranged; and
the two thermoelectric power generation modules form one power generation group, so that the cold water input pipe and the cold water output pipe are located at the same side, while the hot water input pipe and the hot water output pipe are located at the same side, which is convenient to manage; secondly, the cold water input manifolds and the cold water output manifolds are alternately arranged; and the hot water input manifolds and the hot water output manifolds are alternately arranged, so that a space is reasonably utilized.

2. The modular geothermal power generation system according to claim 1, wherein the modular geothermal power generation system further comprises a bracket for fixing the thermoelectric power generation module; the bracket comprises a bottom plate, a supporting plate is arranged in a middle part of the bottom plate, two side faces of the supporting plate are respectively connected with a plurality of bearing plates arranged at intervals, and the thermoelectric power generation module is fixed on the bearing plates.

3. The modular geothermal power generation system according to claim 1, further comprising a box body, wherein the thermoelectric power generation module, the cold water supply system, the hot water supply system and the bracket are all arranged in the box body, and an outer side of the box body is provided with an interface connected with the cold water supply system and an interface connected with the hot water supply system.

4. The modular geothermal power generation system according to claim 3, wherein a control system is arranged at an upper end of the box body, and the control system is used for monitoring a working state of the cold water supply system, a working state of the hot water supply system and a working state of the thermoelectric power generation module.
